(19) United States
(12) Patent Application Publication
(10) Pub. No.: US 2003/0111709 A1
(43) Pub. Date: Jun. 19, 2003

(54) Packing device for embedding a capacitor on chip

(75) Inventors: Wei-Feng Lin, Hsinchu (TW); Ming-Huan Lu, Hsinchu Hsien (TW); Chung-Ju Wu, Kaohsiung (TW)

Correspondence Address: LADAS & PARRY, 26 WEST 61ST STREET, NEW YORK, NY, 10023, US

(73) Assignee: Silicon Integrated Systems Corporation

(21) Appl. No.: 10/165,934

(22) Filed: Jun. 10, 2002

(30) Foreign Application Priority Data
Dec. 19, 2001 (TW) 090131512

(51) Int. Cl. H01L 23/48; H01L 29/00

(52) U.S. Cl. 257/532; 257/528; 257/723; 257/924; 257/690

(57) ABSTRACT

The present invention discloses a packaging device, which embeds a capacitor on a chip so as to effectively filter out the current noise. The packaging device of the invention includes a substrate, a chip, and at least one capacitor. The chip is configured on the substrate and includes at least one power line and ground line. The at least one capacitor is configured on the surface of the chip and electrically connected to the power line and ground line. Furthermore, the invention can configure at least one capacitor on a carrier board attached on the surface of the chip, and the at least one capacitor is electrically connected to the power line and ground line through circuits of the carrier board.

### BACKGROUND OF THE INVENTION

1. Field of the Invention

The present invention relates to a packaging device, and more particularly to a packaging device for embedding at least one capacitor on the surface of a chip to improve the electrical characteristics.

2. Description of Related Art

Following the progress of semiconductor process technology, it is common that there are hundreds of thousands or even millions of transistors built in an IC. If the hundreds of thousands of transistors are operated at the same time, for example being turned on or off at the same time, it will cause a transient pulse effect and electrical noise for the power supply, which makes the operational result unstable.

Conventionally, to solve the problem of voltage stability and electrical noise for the power supply, a plurality of capacitors are added to the circuit board of the IC package to eliminate the electrical noise. For example, a 3D view of the conventional plastic ball grid array packaging device is shown in FIG. 1. A ball grid array packaging device 11 is attached on a circuit board 13, and the periphery of the ball grid array packaging device 11 is configured with a plurality of external capacitors 12. Each of the plurality of external capacitors 12 is electrically connected to the power plane and the ground plane of the ball grid array packaging device 11 so as to eliminate the electrical noise between the power plane and the ground plane. However, the conventional method will make the circuit board 13 full of different sizes and types of capacitors that will not only result in the drawbacks of high cost and larger area, but also not meeting the requirement of being light, thin, short and small for the present high-tech products.

As shown in FIG. 2, an ROC patent No. 445556, entitled “Ball grid array packaging device for reducing electrical noise” and invented by one of the inventors of the application, discloses a semiconductor package attaching a plurality of internal capacitors 23 on a die 21, and the plurality of internal capacitors 23 will directly electrically connect or pass through a conductive hole to contact the power plane 25 and the ground plane 24 for effectively achieving the functions of voltage stabilizing and electrical noise filtering. Nevertheless, there still exists a distance between the capacitors 23 and the chip by the above method so that the electrical problems of noise and voltage drop still exist when the chips operate in high speed.

U.S. Pat. No. 6,285,070 discloses a process technology for forming the capacitor on the surface of semiconductor chips. By the above method, the capacitors are formed on the chip directly and become one layer of the chip. However, the U.S. patent only uses the die-level capacitor with only hundreds of Pico Farads. The application is rather limited comparatively.

Since the operation speed of semiconductor chip gets higher and higher, and the operation voltage of which gets lower and lower, how to make the operating voltage stable and effectively control the electrical noise has become an very important issue.

### SUMMARY OF THE INVENTION

The major object of the invention is to provide a packaging device for embedding capacitors on a chip so as to effectively eliminate the electrical problem, such as voltage drop and capacitance noise.

The second object of the invention is to provide a packaging device to reduce the area occupied by the motherboard or IC substrate, and to reduce the number of the manufacture steps required for the motherboard or IC substrate.

To achieve the above objects, the invention discloses a packaging device, which embeds the capacitor on the chip so as to avoid a long conductive path starting from an external capacitor, passing through I/O pads, and electrically connecting to the power line and ground line inside the chip finally. In other words, the present invention shortens the conductive path for avoiding the problem of voltage drop. Furthermore, the capacitor of the invention may use the capacitor of larger than microfarad level, and will not be constrained by the existing processing technology. Thus, the invention can effectively filter out the current noise.

The packaging device of the invention includes a substrate, a chip, and at least one capacitor. The chip is configured on the substrate and includes at least one power line and ground line. The at least one capacitor is configured on the surface of the chip and electrically connected to the power line and ground line. Furthermore, the invention can configure at least one capacitor on a carrier board attached on the surface of the chip, and the at least one capacitor is electrically connected to the power line and ground line through circuits of the carrier board.

### BRIEF DESCRIPTION OF THE DRAWINGS

The present invention will be described according to the appended drawings in which:

FIG. 1 shows an elevational view of a prior plastic ball grid array packaging device;

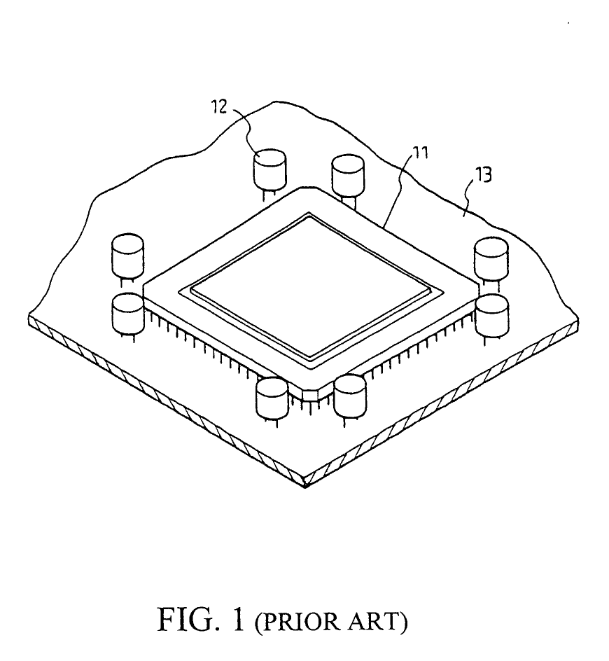

FIG. 2 shows a top view of a prior embedded capacitor substrate;

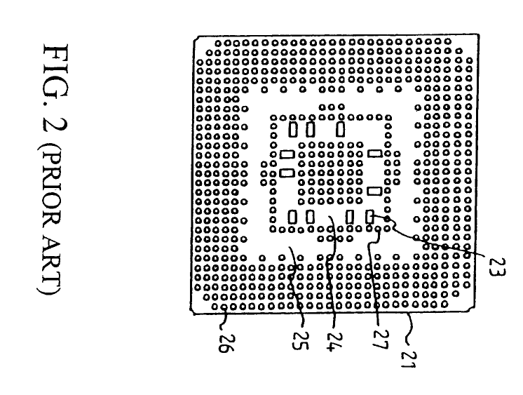

FIG. 3 shows an elevational view of the packaging device according to a first embodiment of the present invention; and

FIG. 4 shows an elevational view of the packaging device according to a second embodiment of the present invention.

### PREFERRED EMBODIMENT OF THE PRESENT INVENTION

Hereafter the preferred embodiments of the invention will be described in the accompanied drawings, wherein the size of each element in the drawings is not equally proportional to the real element, explained hereby.

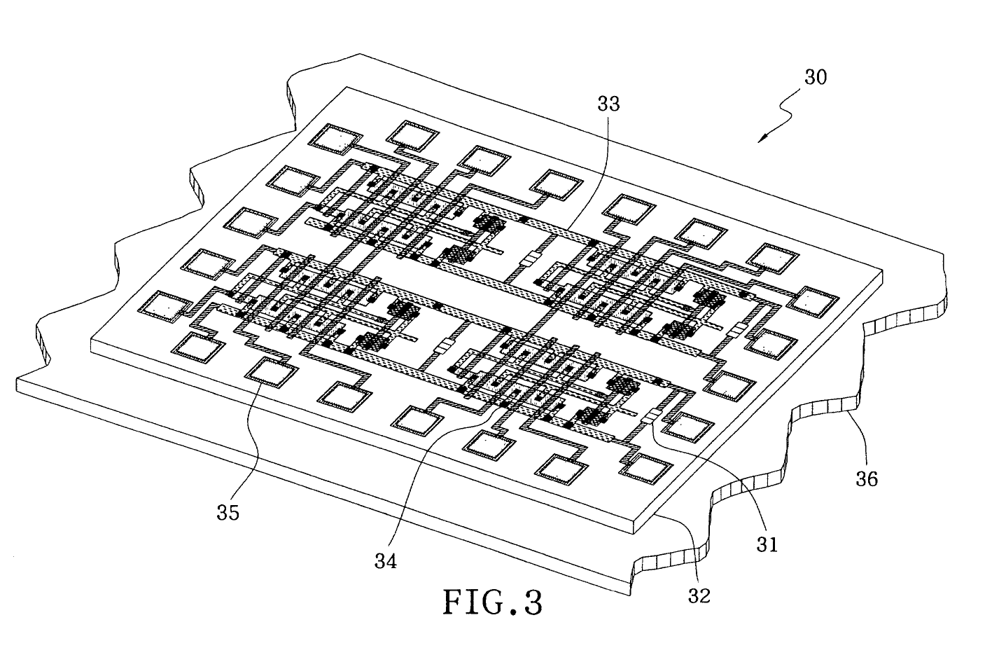

FIG. 3 shows an elevational view of the packaging device according to a first embodiment of the present invention. As shown in the figure, the packaging device 30 of the embodiment includes a substrate 36, a chip 32 and a plurality of capacitors 31 embedded in the chip 32. The substrate 36 serves as a carrier for carrying the chip 32, and may be used in a ball grid array package or may be equivalently replaced by a leadframe. The plurality of capacitors 31 are electrically connected between the power line (V_{dd}) 33 and the ground line (Vₛₛ) 34 of the layout on the surface of the chip 32 by conductive glue or solder. In other words, the external capacitor in prior art is configured outside the chip 32, which needs to electrically connect to the power line 33 and the ground line 34 through the I/O pad 35, so that the total conductive path is too long to cause a voltage drop. Relatively, the invention attaches the plurality of capacitors 31 directly between the power line 33 and the ground line 34 on the surface of the chip 32, in which the conductive path is the shortest so as to effectively reduce the effect of the voltage drop. Furthermore, the capacitor in the embodiment may use the capacitance with above the microfarad level. Thus, the invention can effectively filter out the noise in the current.

As for the size of the capacitor 31, if the employed packaging device is in a bare-crystal form, the size range of the capacitor 31 attached on the chip 32 may be larger, and the capacitors could be even directly placed between the power line 33 and the ground line 34. However, if the employed packaging device needs to process an encapsulation, the size of the capacitor needs to match the height of the encapsulation. Especially during the current trend for the light, thin, short and small products, thin package (the height of the entire device being smaller than 1 mm) is quite popular. In such case, it is especially necessary to take care of the size problem of the employed capacitor. Furthermore, the invention may be applied to traditional quad flat package (QFP), ball grid array package (BGA), chip on board package or flip chip package, which are not limited in the invention.

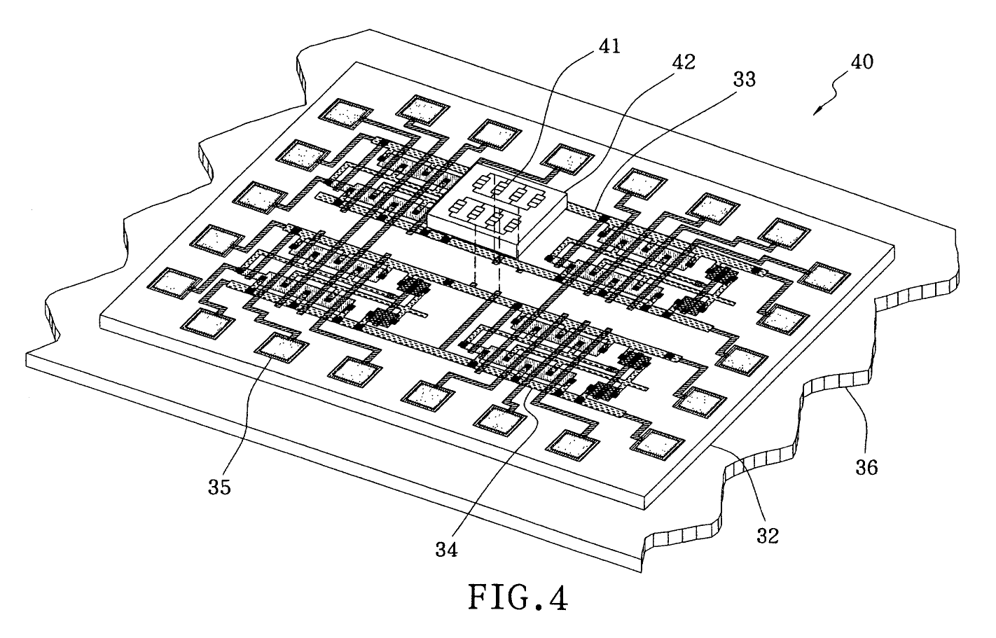

FIG. 4 shows an elevational view of the packaging device according to a second embodiment of the present invention. As shown in the figure, the plurality of capacitors 41 of the embodiment are not directly placed on the surface of the chip 32, but are directly configured on a carrier socket 42 in parallel connection. The material of the carrier socket 42 may be a flexible circuit board or a carrier board. Thereafter, the carrier socket 42 is attached on the surface of the chip 32, and electrically connected to the power line (V_{dd}) 33 and the ground line (Vₛₛ) 34 through a preserved circuit. Since the plurality of capacitors 41 may be floorplanned on the carrier socket 42 in advance, e.g. performing a parallel connection for increasing the capacitance, so that it will be with more flexibility in the application. Besides, the carrier socket 42 of the embodiment may be configured on the upper surface or the lower surface of the chip 32 without influencing the layout of the chip, so that such a layout will make the design of the whole package 40 have more flexibility.

The capacitor configuration of the invention provides the following advantages:

(1) Improving the electrical characteristics of the products. The capacitor of the invention may be built in the surface of the chip directly, and the distance between the power line and ground line of the chip is the shortest, thus the permanently electrical problem of electrical noise and voltage drop may be solved. An experimental result of the invention uses a voltage of 1.8 volt, a power of 3.6 watt, and eight capacitors for connecting the power line 33 and ground line 34. According to the measurement result, the capacitor built in the package of the chip of the invention may reduce about 45% of power noise.

(2) Saving the space occupied by the motherboard or IC substrate. Since the plurality of capacitors of the present invention are properly established on the surface of the chip, the steps for establishing the capacitor on the motherboard or IC substrate may be omitted. The invention not only reduces the space occupied by the motherboard or IC substrate, but also effectively reduces the manufacture steps for the motherboard or substrate.

The above-described embodiments of the present invention are intended to be illustrated only. Numerous alternative embodiments may be devised by those skilled in the art without departing from the scope of the following claims.

What is claimed is:

1. A packaging device for embedding a capacitor on chip, comprising:
a substrate;
a chip placed on said substrate, said chip including at least one power line and ground line; and
at least one capacitor embedded on said chip and electrically connected to said power line and ground line.

2. The packaging device of claim 1, wherein said capacitor has a capacitance of larger than microfarad level.

3. The packaging device of claim 1, wherein said capacitor is adhered on said chip with conductive glue.

4. The packaging device of claim 1, wherein said capacitor is fixed on said chip by soldering.

5. The packaging device of claim 1, wherein said substrate is electrically connected to said chip by wire bonding or flip chip package.

6. A packaging device for embedding a capacitor on chip, comprising:
a substrate;
a chip placed on said substrate, said chip including at least one power line and ground line;
a carrier socket placed on said chip; and
at least one capacitor placed on said carrier socket and electrically connected to said power line and ground line.

7. The packaging device of claim 6, wherein said carrier socket is a flexible circuit board or a carrier board.

8. The packaging device of claim 6, wherein said capacitor has a capacitance of larger than microfarad level.

9. The packaging device of claim 6, wherein said capacitors on said carrier socket are electrically connected to each other.

10. The packaging device of claim 6, wherein said substrate is electrically connected to said chip by wire bonding or flip chip package.
